(19) United States
(12) Patent Application Publication
(10) Pub. No.: US 2024/0305113 A1
(43) Pub. Date: Sep. 12, 2024

(54) METHOD FOR CONTROLLING A DEVICE, AND CIRCUIT DEVICE

(71) Applicant: Robert Bosch GmbH, Stuttgart (DE)

(72) Inventor: Samuel Vasconcelos Araujo, Esslingen Am Necker (DE)

(21) Appl. No.: 18/550,025

(22) PCT Filed: Apr. 26, 2022
(86) PCT No.: PCT/EP2022/060996

§ 371 Date: Sep. 11, 2023

(30) Foreign Application Priority Data
Apr. 30, 2021 (DE) 10 2021 204 358.5

(51) Int. Cl. H02J 7/00

(52) U.S. Cl. CPC H02J 7/0031; H02J 7/00304

(57) ABSTRACT

A method for controlling a device for enabling and interrupting a flow of electric current between a battery and a load or a charging device. The device includes at least one transistor. The gate voltage is set on the basis of a current flowing through the at least one transistor and/or a temperature of the at least one transistor. A circuit device is also described.

### FIELD

The present invention relates to a method for controlling a device for enabling and interrupting a flow of electric current between a battery and a load or a charging device, and to a circuit device.

### BACKGROUND INFORMATION

In the related art, a battery or a lithium-ion battery is electrically connected to or electrically disconnected from various loads or current sources of hybrid or electric vehicles in a reversible manner via an electronic device in the form of a battery disconnect unit (BDU). Such loads include, for example, electric drive trains, traction converters and charging devices.

A typical task of this electronic device is the controlled switching on and off of the battery during driving and charging. A further task of the electronic device is to reliably disconnect the battery from all other components that are electrically connected thereto in the event of a fault.

An electronic device that comprises a P-channel metal-oxide-semiconductor field-effect transistor (MOSFET) is described in U.S. Patent Application Publication No. US 2018/131178 A1.

A further electronic device that comprises an N-channel MOSFET is described in Japan Patent Application No. JP 2010081757 A.

Relatively long operating times are another requirement for the electronic device. A traction inverter, which is electrically connected to the electronic device as a load, is usually designed for approximately 8,000 operating hours during its lifetime of 15 years. As the central unit in hybrid and electric vehicles, the operating time of the electronic device thus corresponds to the sum of the operating times of all loads and current sources. Furthermore, the electronic device is also provided so as to reliably block a current when it is switched off. Therefore, the electronic device is almost always under an electrical load.

The lifetime of such an electronic device usually depends on the lifetime of the transistors contained therein. This in turn depends on a gate voltage of the transistor. The higher the gate voltage selected and the longer the gate voltage is applied to the transistor, the shorter the expected lifetime of the transistor.

### SUMMARY

According to the present invention, a method for controlling a device for enabling and interrupting a flow of electric current between a battery and a load or a charging device, and a circuit device are provided. The device for enabling and interrupting a flow of electric current between a battery and a load or a charging device corresponds in its operation to an above-described electronic device in the form of a battery disconnect unit (BDU), for example, and comprises at least one transistor.

According to the method according to an example embodiment of the present invention, a gate voltage of the at least one transistor is set on the basis of a current flowing therethrough. Alternatively or additionally, the gate voltage is set on the basis of a temperature of the at least one transistor.

An advantage of the method according to the present invention is that the gate voltage of the at least one transistor is adapted in different operating states thereof with respect to the current flowing therethrough or the temperature thereof. In this way, the conduction losses of the at least one transistor can be reduced because the gate voltage has a direct influence on these conduction losses. The lifetime of the at least one transistor is thus extended.

Further advantageous embodiments of the present invention are disclosed herein.

Advantageously, according to an example embodiment of the present invention, the gate voltage is increased when the current flowing through the at least one transistor exceeds a first predetermined value. In this case, this first predetermined value refers, for example, to an operating current of the at least one transistor.

As a result, the conduction losses caused by higher currents in the region of the transistor and also a high thermal load of the at least one transistor caused thereby are reduced.

Further advantageously, according to an example embodiment of the present invention, the gate voltage is reduced when the current flowing through the at least one transistor falls below a second predetermined value. This second predetermined value can, for example, be equal to the first predetermined value and represent an operating current of the at least one transistor.

Because the current flowing through the transistor is relatively low in this second case and therefore does not cause critical conduction losses, the gate voltage can be reduced and the affected transistor is thus relieved.

Further advantageously, according to an example embodiment of the present invention, the gate voltage is set to a negative value for a predetermined period of time as soon as the device has been switched on and as long as the current flowing through the at least one transistor is not constant.

In this way, the switching on of the relevant transistor is accelerated.

Further advantageously, according to an example embodiment of the present invention the gate voltage is set to a negative value for a further predetermined period of time as soon as the device has been switched off and as long as the current flowing through the at least one transistor is greater than 0 amperes (A).

In this way, the switching off of the relevant transistor is accelerated.

The gate voltage is particularly advantageously set to 0 volts (V) when the device has been switched off and as soon as the current flowing through the at least one transistor is 0 A.

As a result of this, the relevant transistor is kept in a blocked state if the relevant transistor is a metal-oxide-semiconductor field-effect transistor (MOSFET).

Alternatively, according to an example embodiment of the present invention, the gate voltage is set to a negative value when the device has been switched off and as soon as the current flowing through the at least one transistor is 0 A.

As a result of this, the relevant transistor is kept in a blocked state if the relevant transistor is a traction inverter.

In this way, the at least one transistor in the form of a MOSFET or a traction inverter is reliably kept in a blocked state.

The described method according to the present invention can advantageously be used for controlling a device for enabling and interrupting a flow of electric current between a battery and a load or a charging device in an electric vehicle (EV), in a hybrid vehicle (HEV) or in a plug-in hybrid vehicle (PHEV).

According to a further aspect of the present invention, a circuit device comprising means (i.e., an arrangement) for carrying out an above-described method is provided. The circuit device can be, for example, an above-described device for enabling and interrupting a flow of electric current between a battery and a load or a charging device. Alternatively, the circuit device may also be a USB mass storage device in which data for performing the above-described method are stored.

### BRIEF DESCRIPTION OF THE DRAWINGS

Advantageous embodiments of the present invention are illustrated in the figures and explained in more detail in the following description of the figures.

FIG. 1 shows a sectional view of a device for enabling and interrupting a flow of electric current between a battery and a load or a charging device, according to an example embodiment of the present invention.

FIG. 2 shows an exemplary sequence chart of a gate voltage curve in each case at a first and a second temperature over the current according to a method according to the present invention.

FIG. 3 shows an exemplary sequence chart of a current or gate voltage curve over time according to a further method according to the present invention.

### DETAILED DESCRIPTION OF EXAMPLE EMBODIMENTS

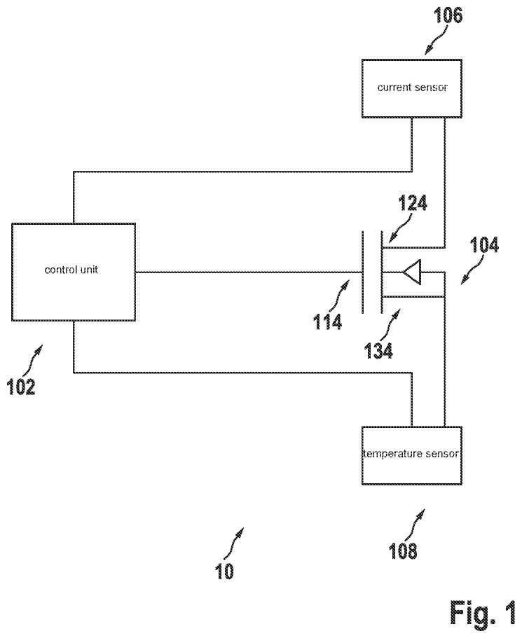

FIG. 1 is a sectional view of a device 10 for enabling and interrupting a flow of electric current between a battery and a load or a charging device.

The device 10 comprises, for example, a control unit 102 and a transistor 104. The transistor 104 may be, for example, a P-channel MOSFET and comprises three terminals 114, 124, 134. In this case, the gate terminal 114 is electronically connected to the control unit 102. In addition to the control unit 102, the drain terminal 124 is electronically connected to a current sensor 106, for example. The source terminal 134 is electronically connected to a temperature sensor 108 in addition to the control unit 102. The operation of the transistor 104 is controlled by the control unit 102. This can be done in that a current and gate voltage curve of the transistor 104 to be achieved is stored in the control unit 102.

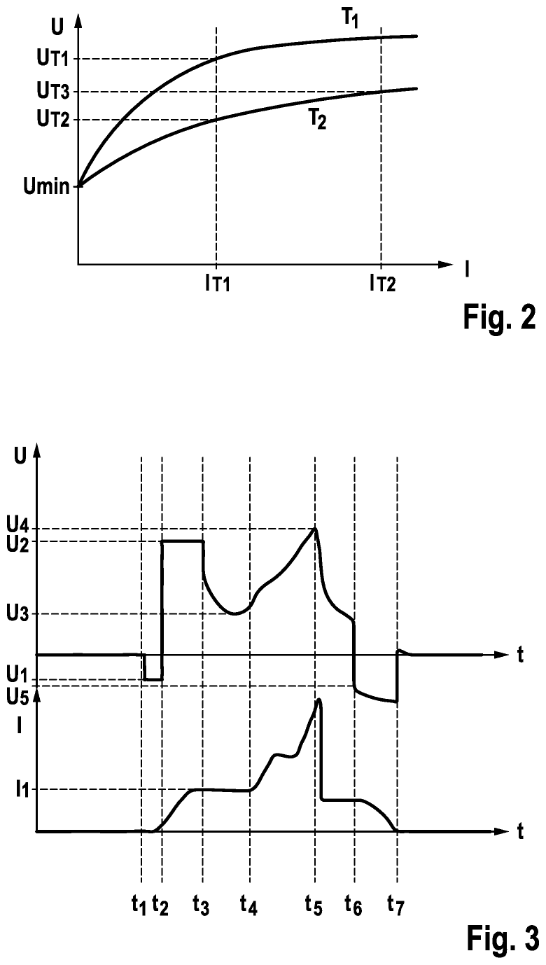

FIG. 2 shows an exemplary sequence chart of a gate voltage curve of a transistor 104 of a device 10 according to FIG. 1 over the current in each case at a first and a second temperature.

In this case, a minimum gate voltage Uₘᵢₙ is required in order to activate the transistor 104. The first gate voltage curve over the current at a first temperature T₁ or the second gate voltage curve over the current at a second temperature T₂ shows that the gate voltage is increased as the current increases while the temperature remains constant. For example, the gate voltage of the transistor 104 is increased from U_{T2} to U_{T3} when the current flowing through the transistor 104 increases from I_{T1} to I_{T2} while the temperature of the transistor 104 is kept constant at T₂.

Furthermore, the two curves show that the gate voltage is increased as the temperature increases while the current remains constant. For example, the gate voltage of the transistor 104 is increased from U_{T2} to U_{T1} when the temperature of the transistor 104 increases from T₂ to T₁ while the current flowing through the transistor 104 is kept constant at I_{T1}.

FIG. 3 shows an exemplary sequence chart of a current or a voltage curve of a transistor 104 of a device 10 according to FIG. 1 over time according to a further method according to the present invention.

The lower chart shows a current curve over time t. A corresponding voltage curve over time t is shown in the upper chart.

The transistor 104 remains deactivated up to time t₁. The current flowing through the transistor 104 during this period of time is therefore 0 A. At time t₁, the device 10 is switched on. At this time, a negative gate voltage U₁ is applied to a gate terminal 114 of the transistor 104 for a first period of time from t₁ to t₂ to activate the transistor 104 as quickly as possible because the transistor 104 is a P-channel MOSFET that is activated with a negative gate voltage. Up to time t₂, the gate voltage is increased to U₂ as soon as the transistor 104 is activated.

After the device 10 is switched on, the current flowing through the transistor 104 increases during a second period of time from t₂ to t₃, until the current has reached a constant value of I₁.

During this second period of time, the gate voltage is, for example, kept unchanged at a voltage U₂.

During a third period of time from t₃ to ty, the current flowing through the transistor 104 remains unchanged, for example. This current I₁ is also referred to as the operating current. Accordingly, the gate voltage is reduced to U₃ during this third period of time because the current I₁ does not have a significant effect on the conduction losses of the transistor 104.

The current increases, for example, during a fourth period of time from t₄ to t₅ and exceeds the operating current I₁, for example due to an increased temperature of the transistor 104. In order to reduce the conduction losses of the transistor 104, the gate voltage is increased to U₄ until time t₅, at which time the current drops again. The reduction in current intensity can be achieved, for example, by cooling the transistor 104.

During a fifth period of time from t₅ to t₆, the current is, for example, again equal to the operating current Ij according to the period of time from t₃ to t₄. Accordingly, the gate voltage is reduced to U₅.

At time to, the device 10 is switched off. In order to block the transistor 104 as quickly as possible, a negative voltage is applied to the gate terminal 114 of the transistor 104 until the current flowing through transistor 104 is equal to 0 A. The transistor 104 is kept in a blocked state from the time t₇. In the blocked state, the gate voltage is 0 V.

1-9. (canceled)

10. A method for controlling a device for enabling and interrupting a flow of electric current between a battery and a load or a charging device, the device including at least one transistor, the method comprising:
setting a gate voltage of the at least one transistor based on: i) a current flowing through the at least one transistor, and/or a temperature of the at least one transistor.

11. The method according to claim 10, further comprising:
increasing the gate voltage when the current flowing through the at least one transistor exceeds a first predetermined value.

12. The method according to claim 10, further comprising:
reducing the gate voltage when the current flowing through the at least one transistor falls below a second predetermined value.

13. The method according to claim 10, further comprising:
setting the gate voltage to a negative value for a predetermined period of time as soon as the device has been switched on and the current flowing through the at least one transistor is not constant.

14. The method according to claim 10, further comprising:
setting the gate voltage is set to a negative value for a further predetermined period of time as soon as the device has been switched off and the current flowing through the at least one transistor is greater than 0 amperes.

15. The method according to claim 10, further comprising:
setting the gate voltage 0 volts or to a negative value when the device has been switched off and the current flowing through the at least one transistor is equal to 0 A.

16. The method according to claim 15, wherein the at least one transistor is a metal-oxide-semiconductor field-effect transistor (MOSFET) or a traction inverter.

17. The method according to claim 10, wherein the device is controlled in an electric vehicle, or in a hybrid vehicle, or in a plug-in hybrid vehicle.

18. A circuit device, comprising:
an arrangement configured to control a device for enabling and interrupting a flow of electric current between a battery and a load or a charging device, the device including at least one transistor, the arrangement configured to:
set a gate voltage of the at least one transistor based on: i) a current flowing through the at least one transistor, and/or a temperature of the at least one transistor.
